(19) United States
(12) Patent Application Publication
(10) Pub. No.: US 2022/0396873 A1
(43) Pub. Date: Dec. 15, 2022

(54) RAW MATERIAL GAS SUPPLY SYSTEM AND RAW MATERIAL GAS SUPPLY METHOD

(71) Applicant: Tokyo Electron Limited, Tokyo (JP)

(72) Inventors: Tsuneyuki OKABE, Yamanashi (JP); Shigeyuki OKURA, Yamanashi (JP); Eiichi KOMORI, Yamanashi (JP)

(21) Appl. No.: 17/636,430

(22) PCT Filed: Aug. 18, 2020
(86) PCT No.: PCT/JP2020/031087

§ 371 Date: Feb. 18, 2022

(30) Foreign Application Priority Data
Aug. 27, 2019 (JP) 2019-154553

(51) Int. Cl. C23C 16/448; C23C 16/52

(52) U.S. Cl. CPC C23C 16/4481; C23C 16/52

(57) ABSTRACT

A raw material gas supply system that supplies a raw material gas generated by vaporizing a solid raw material to a processing apparatus includes: a vaporizer configured to vaporize the solid raw material to generate the raw material gas; a delivery mechanism configured to deliver a solution, in which the solid raw material is dissolved in a solvent, from a solution source storing the solution to the vaporizer; and an evaporation mechanism configured to evaporate the solvent of the solution delivered from the delivery mechanism and accommodated in the vaporizer to separate the solid raw material.

This is a National Phase Application filed under 35 U.S.C. 371 as a national stage of PCT/JP2020/031087, filed Aug. 18, 2020, an application claiming the benefit of Japanese Application No. 2019-154553, filed Aug. 27, 2019, the content of each of which is hereby incorporated by reference in its entirety.

### TECHNICAL FIELD

The present disclosure relates to a raw material gas supply system and a raw material gas supply method.

### BACKGROUND

Patent Document 1 discloses a raw material gas supply apparatus in which a solid raw material is sublimated in a raw material container, a carrier gas is ejected into the raw material container from a carrier gas inlet path, and the sublimated raw material is supplied to a film forming process part together with the carrier gas via a raw material gas flow path. In this raw material gas supply apparatus, the raw material container is configured to be capable of accommodating 5 kg to 60 kg of the solid raw material, and when a remaining amount of the raw material container becomes low, the raw material container is replaced.

### PRIOR ART DOCUMENT

[Patent Document]
Patent Document 1: Japanese Laid-Open Patent Publication No. 2016-191140

### SUMMARY

The technology according to the present disclosure allows a raw material gas supply system, which supplies a raw material gas generated by vaporizing a solid raw material to a processing apparatus, to be replenished with the solid raw material in a manner that does not adversely affect a process in the processing apparatus.

According to an aspect of the present disclosure, a raw material gas supply system for supplying a raw material gas generated by vaporizing a solid raw material to a processing apparatus includes: a vaporizer configured to vaporize the solid raw material to generate the raw material gas; a delivery mechanism configured to deliver a solution, in which the solid raw material is dissolved in a solvent, from a solution source storing the solution to the vaporizer; and an evaporation mechanism configured to evaporate the solvent of the solution delivered from the delivery mechanism and accommodated in the vaporizer to separate the solid raw material.

According to the present disclosure, a raw material gas supply system that supplies a raw material gas generated by vaporizing a solid raw material to a processing apparatus can be replenished with the solid raw material in a manner that does not adversely affect a process in the processing apparatus.

### BRIEF DESCRIPTION OF DRAWINGS

FIG. 1 is a system configuration view schematically illustrating an outline of a configuration of a raw material gas supply system according to an embodiment.

FIG. 2 is a cross-sectional view illustrating an outline of a configuration of a vaporizer.

FIG. 3 is an explanatory view illustrating one step of a film forming process including a raw material gas supply process using the raw material gas supply system.

FIG. 4 is an explanatory view illustrating another step of the film forming process including the raw material gas supply process using the raw material gas supply system.

FIG. 5 is an explanatory view illustrating another step of the film forming process including the raw material gas supply process using the raw material gas supply system.

FIG. 6 is an explanatory view illustrating another step of the film forming process including the raw material gas supply process using the raw material gas supply system.

FIG. 7 is a partially cut out perspective view illustrating another example of the vaporizer.

FIG. 8 is a perspective view illustrating a first member of a tray assembly of the vaporizer of FIG. 7.

FIG. 9 is a perspective view illustrating a second member of the tray assembly of the vaporizer of FIG. 7.

### DETAILED DESCRIPTION

For example, in a semiconductor device manufacturing process, various kinds of processes such as a film forming process for forming a desired film such as a metallic film are repeatedly performed on a substrate such as a semiconductor wafer (hereinafter, referred to as a “wafer”), whereby a desired semiconductor device is manufactured on the wafer.

In the film forming process, a solid raw material may be heated and vaporized to form a raw material gas.

For example, as described above, Patent Document 1 discloses a raw material gas supply apparatus in which a solid raw material is sublimated in a raw material container, a carrier gas is ejected into the raw material container from a carrier gas inlet path, and the sublimated raw material is supplied to the film forming process part together with the carrier gas via a raw material gas flow path. In this raw material gas supply apparatus, when a remaining amount of the solid raw material in the raw material container becomes low, the raw material is replenished by replacing the raw material container.

When the solid raw material is sublimated in the raw material container and supplied to the film forming apparatus as described above, the raw material container is usually installed in a vicinity of the film forming apparatus. However, in the above-mentioned method of replacing the raw material container and replenishing the raw material to the raw material container, when the raw material container is installed in the vicinity of the film forming apparatus, the exchange work may adversely affect the film forming process.

Therefore, the technology according to the present disclosure allows a raw material gas supply system, which supplies a raw material gas generated by vaporizing a solid raw material to a processing apparatus, to be replenished with the solid raw material in a manner that does not adversely affect a process in the processing apparatus.

Hereinafter, a raw material gas supply system and a raw material gas supply method according to the present embodiment will be described with reference to the drawings. In the specification and drawings, elements having substantially the same functional configurations will be denoted by the same reference numerals and redundant descriptions thereof will be omitted.

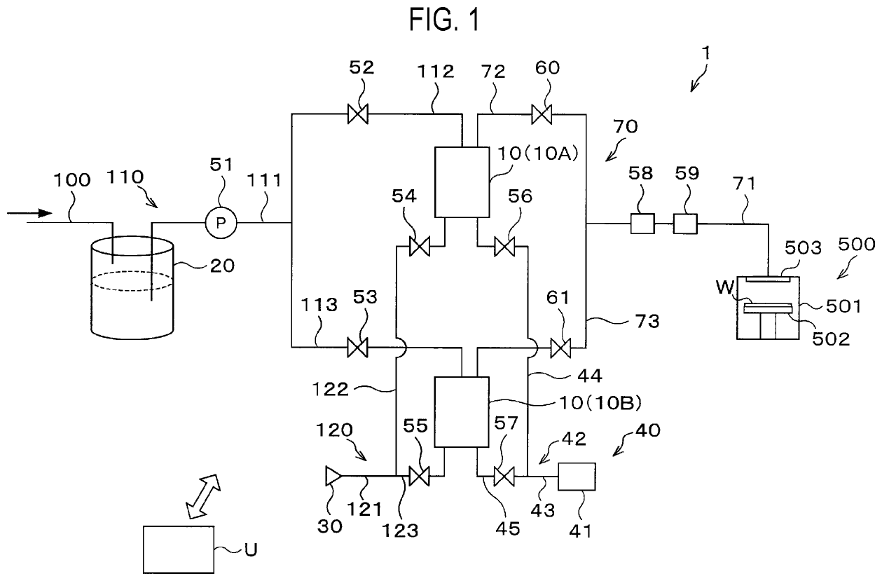

FIG. 1 is a system configuration view schematically illustrating an outline of a configuration of the raw material gas supply system according to the present embodiment. A raw material gas supply system 1 of this example supplies a raw material gas to a film forming apparatus 500 as a processing apparatus that processes a substrate.

As illustrated in FIG. 1, the film forming apparatus 500 includes a processing container 501 configured to be capable of being depressurized, a stage 502 provided in the processing container 501 and configured to horizontally place a wafer W as a substrate thereon, and a gas introduction part 503 configured to introduce a raw material gas or the like into the processing container 501. In the film forming apparatus 500, when the film forming apparatus 500 is supplied with the raw material gas from the raw material gas supply system 1, a tungsten (W) film, for example, is formed through an atomic layer deposition (ALD) method on a surface of the wafer W heated by a heater (not illustrated) of the stage 502. Further, the film forming apparatus 500 is configured such that a reaction gas (a reducing gas) that reacts with the raw material gas or an inert gas can be supplied thereto from a gas source (not illustrated), in addition to the raw material gas.

When the W film is formed in the film forming apparatus 500 as described above, the raw material gas supply system 1 supplies the raw material gas, which is generated by vaporizing a solid raw material such as tungsten chloride (WClₓ) (e.g., WCl₆), to the film forming apparatus 500.

The raw material gas supply system 1 includes, for example, two vaporizers 10 (10A, 10B), a solution source 20, a carrier gas source 30, and a depressurizing mechanism 40.

In the vaporizers 10 (10A, 10B), the solid raw material is separated from a solution obtained by dissolving the solid raw material in a solvent, and the solid raw material is vaporized (sublimated) to generate the raw material gas. The vaporizers 10A and 10B are connected to the film forming apparatus 500 in parallel with each other. In the raw material gas supply system 1, when the solid raw material is replenished to the vaporizers 10 (10A, 10B), the solution in which the solid raw material is dissolved is supplied to the vaporizers 10 (10A, 10B).

The solution source 20 stores the solution. As the solvent of the solution, a solvent having a higher vapor pressure than that of the solid raw material is used. When the solid raw material is WCl₆, ethanol, hexane, toluene, or the like, for example, is used as the solvent.

In addition, a pressurizing gas supply pipe 100 and a solution supply pipe 110 are connected to the solution source 20.

The pressurizing gas supply pipe 100 connects a source (not illustrated) of a pressurizing gas such as Na gas to the solution source 20. The pressurizing gas introduced into the solution source 20 via the pressurizing gas supply pipe 100 presses a liquid surface of the solution in the solution source 20, and the solution is supplied to the solution supply pipe 110.

The solution supply pipe 110 connects the solution source 20 to the vaporizers 10 (10A, 10B). The solution supply pipe 110 includes a common pipe 111 for solution having an upstream end connected to the solution source 20, and branch pipes 112 and 113 for solution branching from a downstream end of the common pipe 111. In addition, a downstream end of the branch pipe 112 is connected to the vaporizer 10A, and a downstream end of the branch pipe 113 is connected to the vaporizer 10B. The common pipe 111 is provided with a pump 51 configured to deliver the solution to the vaporizers 10 (10A, 10B), and the branch pipes 112 and 113 are provided with opening/closing valves 52 and 53, respectively.

In the present embodiment, the pressurizing gas supply pipe, the pump 51, the solution supply pipe 110, and the like form a delivery mechanism, and this delivery mechanism delivers the solution from the solution source 20 to the vaporizers 10 (10A, 10B). When the solution can be delivered from the solution source 20 to the vaporizers 10 (10A, 10B) even only by introducing the pressurizing gas from the pressurizing gas supply pipe, the pump 51 may be omitted.

The carrier gas source 30 stores a carrier gas and supplies the stored carrier gas to the vaporizers 10 (10A, 10B). The carrier gas supplied from the carrier gas source 30 to the vaporizers 10 (10A, 10B) is supplied to the film forming apparatus 500 via a raw material gas supply pipe, which will be described later, together with the raw material gas generated by vaporizing the solid raw material in the vaporizers 10 (10A, 10B).

In addition, a carrier gas supply pipe 120 is connected to the carrier gas source 30.

The carrier gas supply pipe 120 connects the carrier gas source 30 to the vaporizers 10 (10A, 10B). The carrier gas supply pipe 120 includes a common pipe 121 for carrier gas having an upstream end connected to the carrier gas source 30, and branch pipes 122 and 123 for carrier gas branching from a downstream end of the common pipe 121. In addition, a downstream end of the branch pipe 122 is connected to the vaporizer 10A, and a downstream end of the branch pipe 123 is connected to the vaporizer 10B. The branch pipes 122 and 123 are provided with opening/closing valves 54 and 55 as carrier gas supply valves, respectively.

The depressurizing mechanism 40 depressurizes interiors of the vaporizers 10 (10A, 10B). The depressurizing mechanism 40 includes an exhaust pump 41 configured to exhaust the interiors of the vaporizers 10 (10A, 10B), and an exhaust pipe 42 connecting the exhaust pump 41 to the vaporizers 10 (10A, 10B). The exhaust pipe 42 includes a common pipe 43 for exhaust having a downstream end connected to the exhaust pump 41, and branch pipes 44 and 45 for exhaust joining at an upstream end of the common pipe 43. An upstream end of the branch pipe 44 is connected to the vaporizer 10A, and an upstream end of the branch pipe 45 is connected to the vaporizer 10B. The branch pipes 44 and 45 are provided with opening/closing valves 56 and 57, respectively. The depressurizing mechanism 40 forms an evaporation mechanism configured to separate the solid raw material by evaporating the solvent from the solution of the solid raw material in the vaporizers 10 (10A, 10B).

In the raw material gas supply system 1, the vaporizers 10 (10A, 10B) and the film forming apparatus 500 are connected to each other via a raw material gas supply pipe 70. The raw material gas supply pipe 70 includes a common pipe 71 for raw material gas having a downstream end connected to the film forming apparatus 500, and branch pipes 72 and 73 for raw material gas branching from an upstream end of the common pipe 71. An upstream end of the branch pipe 72 is connected to the vaporizer 10A, and an upstream end of the branch pipe 73 is connected to the vaporizer 10B. The common pipe 71 is provided with a mass flow meter 58 and a flow rate control valve 59 in this order from an upstream side, and the branch pipes 72 and 73 are provided with opening/closing valves 60 and 61 as raw material gas supply valves, respectively.

The raw material gas supply system 1 configured as described above is provided with a controller U. The controller U is configured by, for example, a computer including a CPU, a memory, or the like, and includes a program storage (not illustrated). The program storage also stores a program for controlling individual mechanisms, valves, and the like to implement a film forming process including a raw material gas supply process using the raw material gas supply system 1. The program may be recorded in a non-transitory computer-readable storage medium, and may be installed in the controller U from the storage medium. In addition, a part or all of the program may be implemented by dedicated hardware (a circuit board).

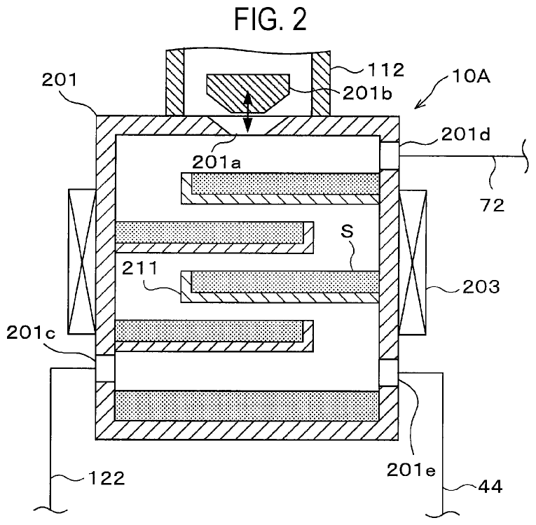

Next, the vaporizers 10 (10A, 10B) will be described with reference to FIG. 2 by taking the vaporizer 10A as an example. FIG. 2 is a cross-sectional view illustrating an outline of a configuration of the vaporizer 10A.

As illustrated in FIG. 2, the vaporizer 10A includes a container 201 as a housing. The solution delivered from the solution source 20 by the delivery mechanism configured by the pump 51 and the like is once contained in the container 201. In the container 201, only the solvent is vaporized (evaporated) from the accommodated solution so that the solid raw material is separated. A separation method will be described later. The container 201 finally accommodates the separated solid raw material. The container 201 is formed of, for example, a metallic material having high thermal conductivity in a cylindrical shape.

A replenishment port 201a to which the downstream end of the branch pipe 112 for solution is connected is formed at a center of a ceiling wall of the container 201. The solution delivered from the solution source 20 is introduced into the vaporizer 10A, that is, into the container 201 via the replenishment port 201a. The replenishment port 201a is provided with a replenishment valve 201b for opening and closing the replenishment port 201a.

In addition, inside the container 201, a plurality of shelves 211 configured to accommodate the solution S is provided. When the solvent of the solution S accommodated on the shelves 211 evaporates, the solid raw material remains on the shelves 211.

The plurality of shelves 211 is stacked in a vertical direction. In addition, shelves 211 adjacent to each other in the vertical direction are provided to protrude in alternating directions. More specifically, each of the shelves 211 has a shape in which an edge portion of a circle in a plan view is cut out, and portions of the shelves 211 adjacent to each other in the vertical direction, which are cut out as described above, face each other with a center of the container 201 interposed therebetween in a plan view.

Since the shelves 211 are provided as described above, a carrier gas flow path having a maze structure (labyrinth structure) is formed in the container 201.

In addition, since the shelves 211 are provided as described above, the solution S supplied from the replenishment port 201a can be supplied to all the shelves 211 sequentially from an upper side.

In this example, the solution S is also accommodated on a bottom wall of the container 201.

The container 201 is provided with a carrier gas inlet port 201c, to which the downstream end of the branch pipe 122 for carrier gas is connected and which is in communication with the carrier gas source 30, and a gas supply port 201d, to which the upstream end of the branch pipe 72 for the raw material gas is connected and which is in communication with the film forming apparatus 500. In this example, the carrier gas inlet port 201c is provided at a lower portion in a side wall of the container 201 on one side in a horizontal direction, and the gas supply port 201d is provided at an upper portion in the side wall of the container 201 on the other side in the horizontal direction. That is, in this example, the carrier gas inlet port 201c and the gas supply port 201d are provided at locations diagonal to each other in the container 201. The carrier gas inlet port 201c is provided at a location between the lowermost shelf 211 and the bottom wall of the container in the side wall of the container on a side of a root of the lowermost shelf 211, and the gas supply port 201d is provided at a location between the uppermost shelf 211 and the ceiling wall of the container in the side wall of the container on a side of a root of the uppermost shelf 211.

In addition, the container 201 is provided with an exhaust port 201e to which the upstream end of the branch pipe 44 for exhaust is connected. An interior of the container 201 is exhausted via the exhaust port 201e. The exhaust of the interior of the container 201 is performed when the solvent of the solution accommodated in the container 201 is evaporated.

A heating mechanism 203 such as a jacket heater is provided around the side wall of the container 201. The heating mechanism 203 heats the container 201 to promote vaporization of the solid raw material in the container 201. In addition, the heating mechanism 203 may be used when evaporating the solvent of the solution in the container 201.

Although a detailed description is omitted, a configuration of the vaporizer 10B is the same as that of the vaporizer 10A. Hereinafter, a container, a replenishment valve, and a heating mechanism included in the vaporizer 10B may be described as the container 201, the replenishment valve 201b, and the heating mechanism 203, as in the case of the vaporizer 10A.

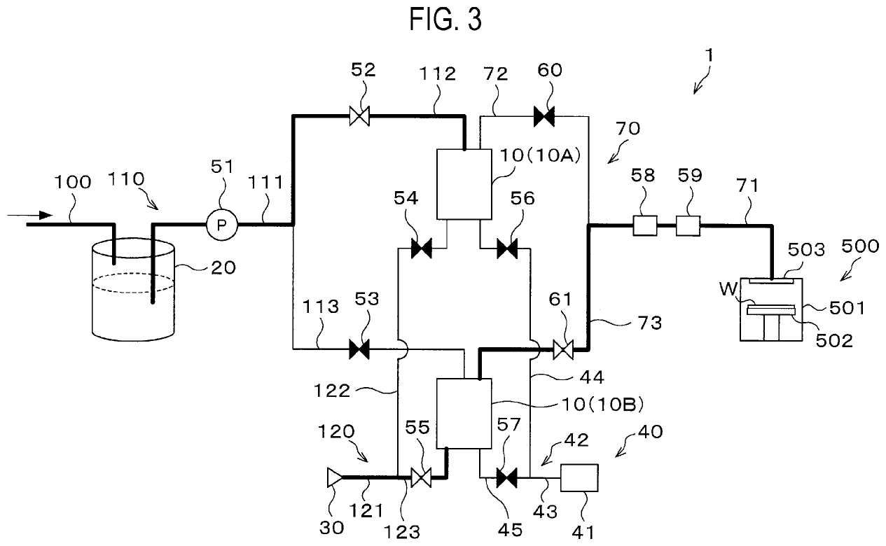

Next, an example of a film forming process including a raw material gas supply process using the raw material gas supply system 1 will be described with reference to FIGS. 3 to 6. In FIGS. 3 to 6, valves in an opened state are indicated by white color, valves in a closed state are indicated by black color, and pipes via which the solution, the carrier gas, or the raw material gas flows is indicated by thick lines, and description as to opened and closed states of other valves will be omitted. In the following description, it is assumed that, at the time of starting the process, the vaporizer 10B is in a state in which replenishment of the solid raw material is not necessary and the vaporizer 10A is in a state in which replenishment of the solid raw material is necessary.

First, in a state in which the replenishment valve 201b (see FIG. 2) and the like of the vaporizer 10B is in a closed state and the vaporizer 10B is heated by the heating mechanism 203, the opening/closing valve 55 of the branch pipe 123 for carrier gas and the opening/closing valve 61 of the branch pipe 73 for raw material gas are opened as illustrated in FIG. 3. As a result, the solid raw material in the container 201 of the vaporizer 10B, which is in communication with the film forming apparatus 500 and depressurized, is vaporized to generate the raw material gas, and the raw material gas is supplied to the film forming apparatus 500 via the branch pipe 73 as the interior of the container 201 is pressurized by the carrier gas. At this time, the opening/closing valve 53 of the branch pipe 113 for solution and the opening/closing valve 57 of the branch pipe 45 for exhaust are in a closed state.

When the raw material gas is supplied to the film forming apparatus 500, the raw material is adsorbed on a surface of the wafer W heated by a heater (not illustrated) of the stage 502.

After a predetermined period of time elapses, the opening/closing valve 61 of the branch pipe 73 for raw material gas is closed, and the supply of the raw material gas to the film forming apparatus 500 is stopped. Subsequently, an inert gas as a replacement gas is supplied from a gas source (not illustrated) to the film forming apparatus 500. After the gas in the processing container 501 is replaced, a reaction gas such as H₂ gas is supplied from a gas source (not illustrated) to the film forming apparatus 500. As a result, a raw material adsorbed on the wafer W is reduced, and a tungsten film having a single atomic layer, for example, is formed.

Subsequently, after the supply of the reaction gas is stopped, the replacement gas is supplied from the gas source (not illustrated) to the film forming apparatus 500, and the gas in the processing container 501 is replaced. Thereafter, the opening/closing valve 61 of the branch pipe 73 for raw material gas is opened, and the supply of the raw material gas is restarted.

By repeating the supply of the raw material gas, the supply of the replacement gas, the supply of the reaction gas, and the supply of the replacement gas described above a plurality of times, a desired film having a desired thickness is formed on the wafer W.

In parallel with the film formation using the raw material gas from the vaporizer 10B as described above, replenishment of the solid raw material to the vaporizer 10A is performed. In other words, when the vaporizer 10B is in a state capable of supplying the raw material gas to the film forming apparatus 500, the solution is delivered from the solution source 20 to the vaporizer 10A, and the solid raw material is separated from the solution in the vaporizer 10A.

Specifically, first, in a state in which the opening/closing valve 53 of the branch pipe 113 for solution is in a closed state and the opening/closing valve 52 of the branch pipe 112 is in an opened state, the replenishment valve 201b of the vaporizer 10A is opened. Then, the pressurizing gas is introduced into the solution source 20 via the pressurizing gas supply pipe 100, and the pump 51 is driven. As a result, the solution in the solution source 20 is supplied to the vaporizer 10A via the common pipe 111 for solution and the branch pipe 112. At this time, the opening/closing valve 54 of the branch pipe 122 for carrier gas and the opening/closing valve 56 of the branch pipe 44 for exhaust are in a closed state.

When a desired amount of solution is accommodated in the container 201 of the vaporizer 10A, specifically, at the timing when a predetermined period of time elapses after starting the introduction of the pressurizing gas into the solution source 20 and the driving of the pump 51, the introduction of the pressurizing gas into the solution source 20 and the driving of the pump 51 are stopped.

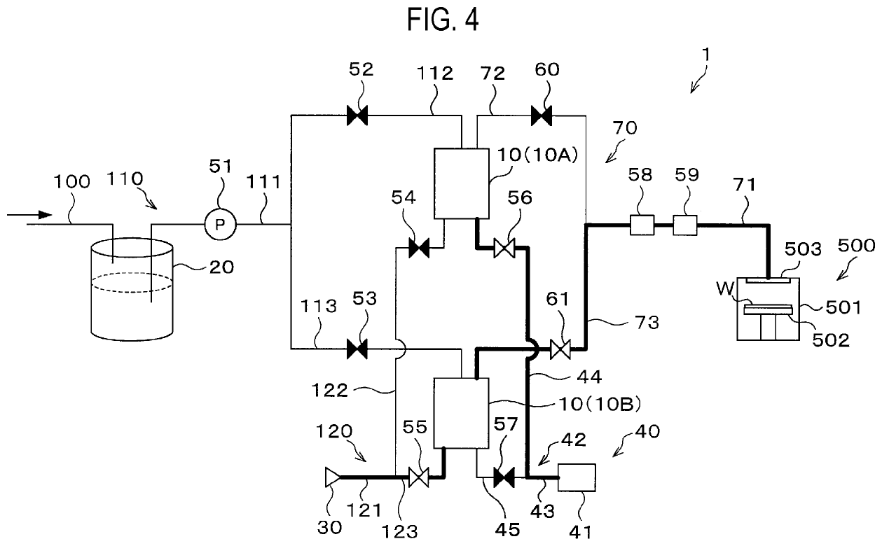

Thereafter, the solvent of the solution accommodated in the container 201 of the vaporizer 10A is evaporated. Specifically, as illustrated in FIG. 4, for example, the opening/closing valve 52 of the branch pipe 112 for solution and the replenishment valve 201b (see FIG. 2) of the vaporizer 10A are closed, and the opening/closing valve 56 of the branch pipe 44 for exhaust is opened. In this state, by driving the exhaust pump 41 to depressurize the interior of the container 201 of the vaporizer 10A, the solvent of the solution in the container 201 evaporates, and the solid raw material is precipitated and remains in the container 201. At the time of the evaporation of the solvent, a pressure in the container 201 is adjusted to be lower than a vapor pressure of the solvent and higher than a vapor pressure of the solid raw material. The opening/closing valve 56 is closed at the timing when the evaporation of the solvent is completed, specifically, at the timing when a predetermined period of time elapses after the opening/closing valve 56 of the branch pipe 44 for exhaust is opened. As a result, the replenishment of the solid raw material to the vaporizer 10A is completed.

When a predetermined period of time elapses from the start of the film formation using the raw material gas from the vaporizer 10B, specifically, after the film formation has been performed on a preset number of wafers W, a source of the raw material gas is switched to the vaporizer 10A because an amount of solid raw material in the vaporizer 10B is reduced.

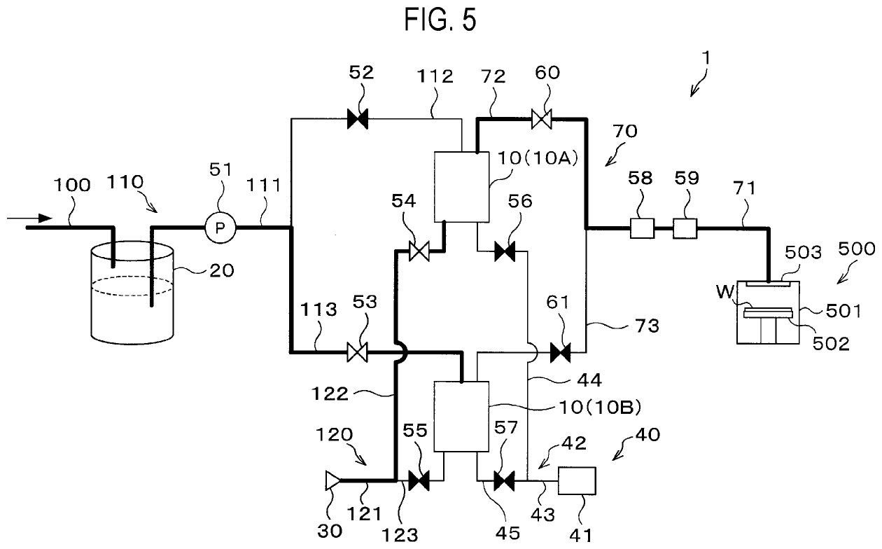

Specifically, first, as illustrated in FIG. 5, the opening/closing valve 61 of the branch pipe 73 for raw material gas connected to the vaporizer 10B and the opening/closing valve 55 of the branch pipe 123 for carrier gas connected to the vaporizer 10B are closed. Then, in a state in which the replenishment valve 201b of the vaporizer 10A is closed and the vaporizer 10A is heated by the heating mechanism 203, the opening/closing valve 54 of the branch pipe 122 for carrier gas and the opening/closing valve 60 of the branch pipe 72 for raw material gas are opened. As a result, the solid raw material in the container 201 of the vaporizer 10A, which is in communication with the film forming apparatus 500 and depressurized, is sublimated to generate the raw material gas, and the raw material gas is supplied to the film forming apparatus 500 via the branch pipe 72 as the interior of the container 201 is pressurized by the carrier gas.

As mentioned above, by repeating the supply of the raw material gas, the supply of the replacement gas, the supply of the reaction gas, and the supply of the replacement gas described above a plurality of times, a desired film having a desired thickness is formed on the wafer W.

In addition, in parallel with the film formation using the raw material gas from the vaporizer 10A as described above, replenishment of the solid raw material to the vaporizer 10B is performed. In other words, when the vaporizer 10A is in a state capable of supplying the raw material gas to the film forming apparatus 500, the solution is delivered from the solution source 20 to the vaporizer 10B, and the solid raw material is separated from the solution in the vaporizer 10B.

Specifically, first, in a state in which the opening/closing valve 52 of the branch pipe 112 for solution is in a closed state and the opening/closing valve 53 of the branch pipe 113 is in an opened state, the replenishment valve 201b of the vaporizer 10B is opened. Then, the pressurizing gas is introduced into the solution source 20 via the pressurizing gas supply pipe 100, and the pump 51 is driven. As a result, the solution in the solution source 20 is supplied to the vaporizer 10B via the common pipe 111 for solution and the branch pipe 113.

At the timing when a desired amount of solution is accommodated in the container 201 of the vaporizer 10B, the introduction of the pressurizing gas into the solution source 20 and the driving of the pump 51 are stopped.

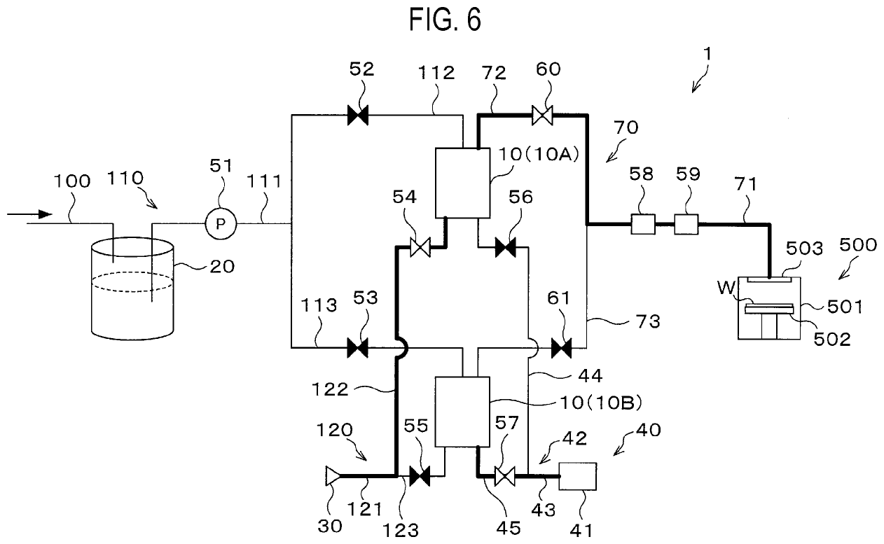

Thereafter, the solvent of the solution in the container 201 of the vaporizer 10B is evaporated. Specifically, as illustrated in FIG. 6, for example, the opening/closing valve 52 of the branch pipe 112 for solution and the replenishment valve 201b (see FIG. 2) of the vaporizer 10B are closed, and the opening/closing valve 57 of the branch pipe 45 for exhaust is opened. In this state, by driving the exhaust pump 41 to depressurize the interior of the container 201 of the vaporizer 10B, the solvent of the solution in the container 201 evaporates, and the solid raw material is precipitated and remains in the container 201. At the timing when the evaporation of the solvent is completed, the opening/closing valve 57 of the branch pipe 45 for exhaust is closed. As a result, the replenishment of the solid raw material to the vaporizer 10B is completed.

In addition, at the time of supplying the solution to the vaporizer 10A, heating the vaporizer 10A by the heating mechanism 203 is stopped. The same applies to the vaporizer 10B.

From a viewpoint of improving an operation rate or the like, during a period after replenishing the solid raw material to the vaporizer 10A and before starting the gas supply from the vaporizer 10A, a preheating process may be performed to heat the container 201 by the heating mechanism 203 to a predetermined temperature (e.g., a temperature from 120 degrees C. to 130 degrees C., which is lower than a sublimation temperature of WCl₆). The same applies to the vaporizer 10B.

When an amount of the raw material gas in the gas supplied from the vaporizers 10A and 10B to the film forming apparatus 500 (hereinafter, referred to as a “pickup amount”) decreases, the solid raw material in an unvaporized state in the vaporizers 10A and 10B may be discharged. An example of a method of discharging such a solid raw material includes: vaporizing the solid raw material by performing at least one of depressurizing the interior of the container 201 by the depressurizing mechanism 40 and heating the solid raw material by the heating mechanism 203; and discharging the gas via the film forming apparatus 500 or the depressurizing mechanism 40.

As described above, in the raw material gas supply system 1 according to the present embodiment, the solution in which the solid raw material is dissolved is delivered from the solution source 20 to the vaporizers 10 (10A, 10B), which generate the raw material gas by vaporizing the solid raw material, by the delivery mechanism. Then, the solid raw material is separated from the solution in the vaporizers 10 (10A, 10B) by the evaporation mechanism configured by the depressurizing mechanism 40 and the like. Therefore, according to the present embodiment, even when the vaporizers 10 (10A, 10B) are installed in the vicinity of the film forming apparatus 500, a work in the vicinity of the film forming apparatus 500 becomes unnecessary at the time of replenishing the solid raw material to the vaporizers 10 (10A, 10B). Therefore, the solid raw material may be replenished to the vaporizers 10 (10A, 10B) in a manner that does not adversely affect the film forming process in the film forming apparatus 500.

In addition, according to the present embodiment, since the solution source 20, which needs to be replaced, does not also serve as a vaporizer, a degree of freedom in installation location thereof is high. Therefore, the solution source 20 can be placed at a location that facilitates a replacement work thereof.

Further, unlike a gas or liquid raw material, since a solid raw material cannot be expected to be heated by, for example, convection heat transfer, it takes a long time to heat the solid raw material. In contrast, with the configuration in which the solution in which the solid raw material is dissolved is supplied by the delivery mechanism to replenish the solid raw material as in the present embodiment, it is possible to adopt a configuration in which the solid raw material is alternately replenished to two vaporizers 10 (10A, 10B). In this configuration in which the solid raw material is alternately replenished, while the raw material gas is being supplied from one vaporizer, replenishment of the solid raw material to the other vaporizer and heating the solid raw material in the other vaporizer can be performed. Therefore, even when the solid raw material that requires a long time for being heated is used, it is possible to prevent a throughput of the film forming process from being lowered due to a waiting time until the solid raw material is heated to a desired temperature.

As a raw material gas supply method different from the present embodiment, it may be considered to supply a liquid raw material obtained by dissolving a solid raw material in a solvent to a vaporizer, and to supply the raw material gas by generating a raw material gas by vaporizing the liquid raw material by a vaporizer. In this method, since the liquid raw material contains carbon of the solvent, a quality of a film formed by the raw material gas may deteriorate. In contrast, in the raw material gas supply method according to the present embodiment, since the raw material gas is generated after the solvent and the solid raw material are separated, in other words, after the solid raw material is precipitated, a high-quality film can be formed.

Further, when directly vaporizing the liquid raw material obtained by dissolving the solid raw material in the solvent, it is necessary for the solvent to have substantially the same vapor pressure as that of the solid raw material. Therefore, a type of solvent is limited. In contrast, when the solid raw material is precipitated from the solution and then vaporized as in the present embodiment, a type of the solvent is not limited because it is basically sufficient that the solvent has a higher vapor pressure than that of the solid raw material.

In addition, in present embodiment, the carrier gas inlet port 201c and the gas supply port 201d are provided at locations diagonal to each other in the container 201. Therefore, since a flow path of the carrier gas in the container 201 is long, a certainly high pickup amount can be obtained.

In addition, in the present embodiment, the raw material gas supply system 1 includes two vaporizers 10A and 10B connected in parallel to each other. Further, when one of the vaporizers 10A and 10B is in a state capable of supplying the raw material gas to the film forming apparatus 500, the solution is delivered from the solution source 20 to the other of the vaporizers 10A and 10B so that the other vaporizer is replenished with the solid raw material. Therefore, it is not necessary to stop the raw material gas supply system 1 when replenishing the solid raw material, and the supply of the raw material gas can be continued. Therefore, the throughput of the film forming process can be improved. Unlike the present embodiment, when there is one vaporizer that also serves as a raw material container and replenishment of a raw material is performed by replacing the vaporizer, that is, by replacing the raw material container, the raw material container may be enlarged and filled with a large amount of solid raw material so that a time period during which the raw material gas supply system is stopped for the replenishment to prevent a decrease in throughput. However, in a case of filling a large amount of substantially expensive solid raw material such as WCl₆ in on container, a significant loss will be incurred when a problem occurs in the container due to an accident or the like during the replacement work thereof. Therefore, it is difficult for a semiconductor manufacturer to adopt the method of filling the container, which needs to be replaced, with a large amount of solid raw material to prevent a decrease in throughput of the film forming process. In contrast, in the present embodiment, the throughput of the film forming process can be improved even when the container, which needs to be replaced, that is, the solution source 20, is not filled with a large amount of solid raw material. Therefore, the solid raw material replenishment method according to the present embodiment can be easily adopted by a semiconductor manufacturer.

In the present embodiment, each of the vaporizers 10 (10A, 10B) is provided with the replenishment valve 201b, which cuts off communication between the solution supply pipe 110 and a corresponding one of the vaporizers 10 (10A, 10B) when the raw material gas is supplied from the corresponding one of the vaporizers 10 (10A, 10B). Therefore, it is possible to prevent an unnecessary gas component from being mixed in the raw material gas.

When the solvent of the solution in the container 201 is evaporated, heating by the heating mechanism 203 may be performed together with the depressurization of the container 201 or instead of the decompression of the container 201. That is, the evaporation mechanism that separate the solid raw material by evaporating the solvent of the solution accommodated in the vaporizers 10 includes at least one of the depressurizing mechanism 40 and the heating mechanism 203.

In the foregoing, a start and stop of the supply of the raw material gas from the vaporizer 10A to the film forming apparatus 500 is switched by using the opening/closing valve 60 provided in the branch pipe 72 for raw material gas. Instead, a switching valve may be provided at a downstream side of the flow rate control valve 59 in the common pipe 71 for raw material gas, and when the raw material gas from the vaporizer 10A is used for film formation, the opening/closing valve 60 of the branch pipe 72 may be kept in an opened state continuously, and the start and stop of the supply of the raw material gas may be switched by the switching valve of the common pipe 71. The same applies to the supply of the raw material gas from the vaporizer 10B.

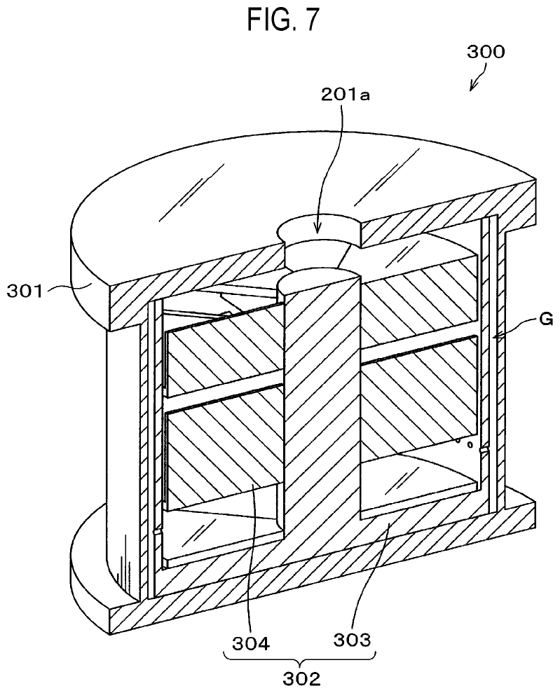

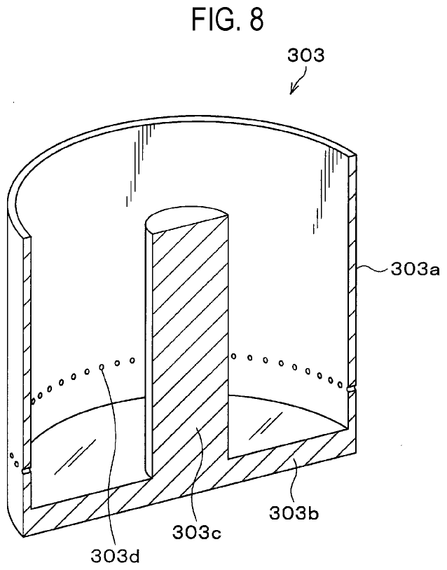

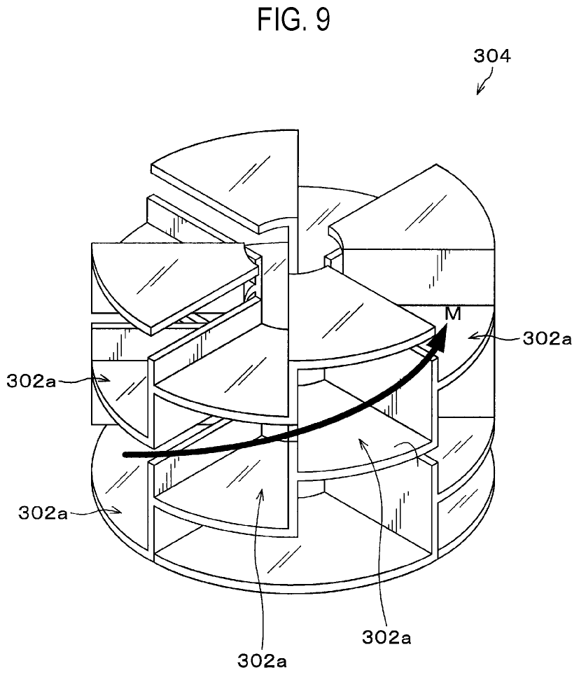

FIGS. 7 to 9 are views illustrating another example of the vaporizer. FIG. 7 is a partially broken perspective view illustrating the vaporizer of another example, and FIGS. 8 and 9 are perspective views illustrating a first member and a second member of a tray assembly to be described later, respectively.

A vaporizer 300 of the example of FIGS. 7 to 9 also includes a plurality of shelves in a container like the vaporizer 10A of FIG. 2. However, in the vaporizer 300, a carrier gas flow path is formed in a spiral shape, and the shelves are provided along the flow path.

The details will be described below.

As illustrated in FIG. 7, the vaporizer 300 includes a tray assembly 302 provided in a container 301.

The container 301 has the same configuration as the container 201 of FIG. 2 and is provided with the replenishment port 201a and the like. Although not illustrated, the container 301 is also provided with the carrier gas inlet port 201c, the gas supply port 201d, and the exhaust port 201e.

The tray assembly 302 includes a first member 303 and a second member 304.

As illustrated in FIG. 8, the first member 303 includes a cylindrical side wall 303a, a disk-shaped bottom wall 303b, and a cylindrical columnar portion 303c extending upward from the bottom wall 303b.

As illustrated in FIG. 7, a gap G is provided between the side wall 303a and an inner peripheral surface of a side wall of the container 301.

In addition, as illustrated in FIG. 8, a plurality of through-holes 303d arranged at equal intervals along a circumferential direction is formed in the side wall 303a. In order to ensure that a carrier gas is supplied to one among the plurality of shelves, which is provided at the lowermost location and will be described later, the through-holes 303d are provided at a location corresponding to the lowermost shelf.

As illustrated in FIG. 9, the second member 304 of the tray assembly 302 is disposed at a location between the side wall 303a and the columnar portion 303c of the first member 303 and on the bottom wall 303b of the first member.

The second member 304 together with the first member 303 form:

(a) a spiral carrier gas flow path centered on a central axis of the container 301 as indicated by arrow M; and

(b) a plurality of shelves 302a arranged along the carrier gas flow path and configured to accommodate a solution.

In the example illustrated in the figures, four carrier gas flow paths are formed.

The carrier gas supplied into the container 301 via the carrier gas inlet port 201c (see FIG. 2) flows into the lowermost shelf 302a via the gap G and the through-hole 303d, flows along the carrier gas flow path, and reaches an interior of the uppermost shelf 302a. Since an upper portion of the uppermost shelf 302a is open in the container 301, the carrier gas that reaches the uppermost shelf 302a is output from the gas supply port 201d (see FIG. 2) together with the raw material gas.

With the vaporizer 300, since the carrier gas flow path is formed in a spiral shape and is long, a high pickup amount can be obtained.

In addition, since the shelves 302a are provided as described above, the solution supplied from the replenishment port 201a can be supplied to all the shelves 302a sequentially from the upper side.

In the above-described examples, the solution is delivered from the solution source 20 to the vaporizers 10 (10A, 10B) by pumping. Instead of this, the delivery of the solution from the solution source 20 to the vaporizers 10A and 10B may be performed by using gravity acting on the solution by arranging the solution source 20 above the vaporizers 10 (10A, 10B).

In the above-described examples, the carrier gas is introduced into the container to flow from the lower side to the upper side in the container of the vaporizer, but the carrier gas may be introduced to flow from the upper side to the lower side.

In addition, in the above-described examples, the carrier gas inlet port 201c, the gas supply port 201d, and the exhaust port 201e are provided independently of the replenishment port 201a, but the carrier gas inlet port 201c, the gas supply port 201d, the exhaust port 201e, and the replenishment port 201a may be shared. For example, when the carrier gas inlet port 201c, the gas supply port 201d, the exhaust port 201e, and the replenishment port 201a are shared, the branch pipes 122 and 123 for carrier gas, the branch pipes 72 and 73 for raw material gas, and branch pipes 44 and 45 for exhaust may be connected to the branch pipes 112 and 113 for solution, respectively.

It should be understood that the embodiments disclosed herein are exemplary in all respects and are not restrictive. The above-described embodiments may be omitted, replaced, or modified in various forms without departing from the scope and spirit of the appended claims.

The following configurations also fall within the technical scope of the present disclosure.

(1) A raw material gas supply system for supplying a raw material gas generated by vaporizing a solid raw material to a processing apparatus, the raw material gas supply system including:

a vaporizer configured to vaporize the solid raw material to generate the raw material gas;

a delivery mechanism configured to deliver a solution, in which the solid raw material is dissolved in a solvent, from a solution source storing the solution to the vaporizer; and

an evaporation mechanism configured to evaporate the solvent of the solution delivered from the delivery mechanism and accommodated in the vaporizer to separate the solid raw material.

According to (1), the solid raw material can be replenished to the raw material gas supply system in a manner that does not adversely affect a process in the processing apparatus.

(2) The raw material gas supply system set forth in (1), wherein the evaporation mechanism includes at least one of a depressurizing mechanism configured to depressurize an interior of the vaporizer and a heating mechanism configured to heat the solution accommodated in the vaporizer.

(3) The raw material gas supply system set forth in (1) or (2), wherein the vaporizer includes a plurality of shelves configured to accommodate the solution.

(4) The raw material gas supply system set forth in (3), wherein the plurality of shelves are stacked in a vertical direction.

(5) The raw material gas supply system set forth in (4), wherein among the plurality of shelves, shelves adjacent to each other in the vertical direction are formed so as to protrude in alternating directions.

According to (5), a carrier gas flow path can be lengthened and the pickup amount can be increased.

(6) The raw material gas supply system set forth in (4), wherein a carrier gas flow path is formed in a spiral shape, and wherein the plurality of shelves is arranged along the carrier gas flow path.

According to (6), the carrier gas flow path can be lengthened and the pickup amount can be increased.

(7) The raw material gas supply system of any one of (1) to (6), further including:

a plurality of vaporizers connected in parallel with one another; and

a controller configured to output a control signal which allows, when a part of the plurality of vaporizers is in a state capable of supplying the raw material gas to the processing apparatus, the solution to be delivered from the solution source to the other part of the plurality of vaporizers such that the solid raw material is separated from the solution in the other part of the plurality of vaporizers.

According to (7), a ratio of the solid raw material in a suspension supplied to the vaporizer can be made uniform.

(8) A method of supplying a raw material gas generated by vaporizing a solid raw material to a processing apparatus, the method including:

delivering a solution, in which the solid raw material is dissolved in a solvent, from a solution source storing the solution to a vaporizer;

separating the solid raw material from the solution in the vaporizer;

vaporizing the separated solid raw material to generate the raw material gas in the vaporizer; and

supplying the generated raw material gas to the processing apparatus.

### EXPLANATION OF REFERENCE NUMERALS

1: raw material gas supply system, 10A, 10B, 300: vaporizer, 20: solution source, 40: depressurizing mechanism, 51: pump, 100: pressurized gas supply pipe, 201a: replenishment port, 201b: replenishment valve, 201c: carrier gas inlet port, 201d: gas supply port, 201e: exhaust port, 203: heating mechanism, 500: film forming apparatus, S: solution

1-8. (canceled)

9. A raw material gas supply system for supplying a raw material gas generated by vaporizing a solid raw material to a processing apparatus, the raw material gas supply system comprising:
a vaporizer configured to vaporize the solid raw material to generate the raw material gas;
a delivery mechanism configured to deliver a solution, in which the solid raw material is dissolved in a solvent, from a solution source storing the solution to the vaporizer; and
an evaporation mechanism configured to evaporate the solvent of the solution delivered from the delivery mechanism and accommodated in the vaporizer to separate the solid raw material.

10. The raw material gas supply system of claim 9, wherein the evaporation mechanism includes at least one of a depressurizing mechanism configured to depressurize an interior of the vaporizer and a heating mechanism configured to heat the solution accommodated in the vaporizer.

11. The raw material gas supply system of claim 10, wherein the vaporizer includes a plurality of shelves configured to accommodate the solution.

12. The raw material gas supply system of claim 11, wherein the plurality of shelves are stacked in a vertical direction.

13. The raw material gas supply system of claim 12, wherein among the plurality of shelves, shelves adjacent to each other in the vertical direction are formed so as to protrude in alternating directions.

14. The raw material gas supply system of claim 13, further comprising:
a plurality of vaporizers connected in parallel with one another; and
a controller configured to output a control signal which allows, when a part of the plurality of vaporizers is in a state capable of supplying the raw material gas to the processing apparatus, the solution to be delivered from the solution source to the other part of the plurality of vaporizers such that the solid raw material is separated from the solution in the other part of the plurality of vaporizers.

15. The raw material gas supply system of claim 12, wherein a carrier gas flow path is formed in a spiral shape, and
wherein the plurality of shelves is arranged along the carrier gas flow path.

16. The raw material gas supply system of claim 9, wherein the vaporizer includes a plurality of shelves configured to accommodate the solution.

17. The raw material gas supply system of claim 9, further comprising:
a plurality of vaporizers connected in parallel with one another; and
a controller configured to output a control signal which allows, when a part of the plurality of vaporizers is in a state capable of supplying the raw material gas to the processing apparatus, the solution to be delivered from the solution source to the other part of the plurality of vaporizers such that the solid raw material is separated from the solution in the other part of the plurality of vaporizers.

18. A method of supplying a raw material gas generated by vaporizing a solid raw material to a processing apparatus, the method comprising:
delivering a solution, in which the solid raw material is dissolved in a solvent, from a solution source storing the solution to a vaporizer;
separating the solid raw material from the solution in the vaporizer;
vaporizing the separated solid raw material to generate the raw material gas in the vaporizer; and
supplying the generated raw material gas to the processing apparatus.
